(19) United States
(12) Patent Application Publication
(10) Pub. No.: US 2004/0257072 A1
(43) Pub. Date: Dec. 23, 2004

(54) Dual-sensitivity eddy current test probe

(76) Inventor: Rock Samson, St. Nicolas (CA)

Correspondence Address: FAY KAPLUN & MARCIN, LLP, Suite 702, 150 Broadway, New York, NY, 10038, US

(21) Appl. No.: 10/464,953

(22) Filed: Jun. 19, 2003

(51) Int. Cl. G01N 27/72; G01R 33/12

(52) U.S. Cl. 324/242; 324/238; 324/220; 324/221

(57) ABSTRACT

The present invention relates to a dual sensitivity eddy current test probe for inspecting a tubular member made of electrically conducting material in order to detect and localize defects in the tubular member, comprising a probe body for movement about a surface of the tubular member, a first test coil assembly for detecting and localizing defects within the tubular member, a first support for the first test coil assembly, a second test coil assembly for acquiring historical data about defects in the tubular member, a second support for the second test coil assembly, and a magnetic coupling interference eliminating system interposed between the first and second test coil assemblies. The first support is mounted on the probe body for holding the first test coil assembly at a first predetermined distance from the surface of the tubular member while the probe body moves about this surface of the tubular member. In the same manner, the second support is mounted on the probe body for holding the second test coil assembly at a second predetermined distance from the surface of the tubular member while the probe body moves about that surface of the tubular member.

### FIELD OF THE INVENTION

The present invention relates to the field of non-destructive testing (NDT). In particular but not exclusively, the present invention addresses the use of eddy current probes to detect defects in the walls of tubing used for example in steam generators, atomic reactors and other applications.

### BACKGROUND OF THE INVENTION

Eddy current probes are well known to those of ordinary skill in the art, and present various configurations depending on the nature of the material being tested. Some eddy current probes are adapted for testing planar surfaces, others for testing tubes. In the latter case, the eddy current probes are designed for testing both the interior and the exterior of the tubes. Eddy current probes designed for inspecting the inside of heat exchanger tubes comprise a probe head with coils for inducing and detecting eddy currents in the conductive tube material being tested.

Non-destructive testing using eddy currents senses the presence of structural defects, such as cracks and corrosion, through variations in conductivity and permeability of the material under test caused by the defects. Since this technique relies upon induced current flow, the tested material is an electrically conductive material. According to this technology, a test coil is placed proximate to the electrically conductive material under test and is supplied with an electrical, alternating drive signal to produce a flow of alternating current through this test coil. The test coil then generates a corresponding alternating magnetic field itself inducing a flow of eddy currents in the electrically conductive material under test. The eddy currents themselves produce a corresponding magnetic field and a counter electro motive force (“EMF”) that is out of phase with respect to the alternating current supplied to the test coil. This counter EMF reduces the voltage and current through the test coil to thereby provide this test coil with apparent inductive impedance.

The impedance of the test coil is a function of the magnitude of eddy current flow in the material under test. Any disruption of the flow of eddy currents in the material under test corresponds to a variation in the apparent inductive impedance of the test coil. For example, flaws in a metal wall, such as cracks, pits, corrosion or regions of local thinning, create regions of higher resistance at the location of the flaws. Therefore flaws and other defects will affect the magnitude of the induced eddy currents whereby these defects can be detected through a measure of variations in the apparent impedance of the test coil. Generally, variations in the impedance of the test coil indicate discontinuities within the material under test. More specifically, sharp variations in impedance over localized areas indicate the existence of cracks or pits or other relatively small-area flaws, whereas gradual changes in impedance over a broad region of a material might indicate large-area flaws such as a grain change in the metal, an area of material creep, or a thinned wall region.

Eddy current probes are particularly useful in inspecting tubes made of a metal alloy sold under the trademark INCONEL and used as heat exchangers in nuclear steam generators. These tubes are inspected for flaws caused by corrosion or fretting. Generally, these tubes are inspected by means of a test coil mounted within the head of a probe designed for sliding and longitudinal movement within the tube to be inspected. Cables supply alternating current to the test coil as it is moved through the tube. Typically, alternating currents having frequencies between 1 kHz and 1 MHz are supplied to the test coil.

The depth of penetration of an alternating magnetic field is dependent upon its frequency, with low frequencies having a greater depth of penetration. However, low frequencies require coils of larger diameter to operate efficiently. On the other hand, small-diameter test coils better discriminate fine structures, and are preferred for locating smaller cracks, smaller defects, etc. Therefore, it is difficult for a test coil to both detect deeper flaws within a conduit wall and accurately pinpoint the location of a given flaw, in particular a small flaw. Trade-offs are required to achieve the best compromise between span of coverage and precision of measurement.

An eddy current testing technique used to inspect tubes incorporates a circumferential coil having an axis that is coaxial with the longitudinal axis of the tube under inspection. This type of probe inspects to a substantial depth an entire cross-section of the tube at once. However, a drawback of this eddy current testing technique resides in its incapacity to detect small volume flaws, long axial flaws, and circumferential flaws due to the orientation of the magnetic field.

A better discriminating technique for detecting flaws relies upon the use of eddy current probes that incorporate one or many smaller coils mounted for rotation. This type of eddy current probe comprises a head containing the coil(s) and moved longitudinally within the tube while being rotated to scan the inner surface of the tube in a helical fashion. The smaller coil or coils interact only with a small portion of the inner surface of the tube at any given time, thereby increasing sensitivity.

In a typical arrangement, a coil is mounted with its geometrical axis parallel to the longitudinal axis of the tube under inspection and is operated in an “absolute” impedance mode. Alternatively, a pair of coils having similar dimensions may be positioned adjacent to each other, optionally with their axes oriented transversely to the longitudinal axis of the tube under inspection, to operate in a “differential” mode. By placing the two coils in a balanced bridge, a very sensitive measure of the impedance of the test coil can be obtained.

In the case of an eddy current probe comprising a “pancake-type” test coil configuration, the axis of the coil is positioned transversal to the longitudinal axis of the conduit, and the coil is used to scan the inner wall of the tube by moving it helically along this inner surface of the tube. Such pancake-type coils are capable of approximating the location of some types of flaws in the wall of the tube while moving rapidly over the inner tube surface under inspection.

Also known is to operate a pair of test coils in transmit-receive mode. According to this design, a first coil of the pair is energized to produce an alternating magnetic field that penetrates the surface of the material under test, while a second coil of the pair is positioned to intercept a portion of the magnetic field that has passed through the material under test to generate a corresponding voltage induced in this second coil by the said portion of the magnetic field.

Ideally, coils used to induce eddy currents are positioned adjacent to a surface of the material to be tested, with a constant spacing between the coil and this surface. Variations in the spacing between the test coil and the material will produce undesirable variations in the apparent impedance of the test coil, complicating the objective of obtaining consistent and reliable test measurements. The undesired signal artefact that arise from spacing variations are known as probe spacing, probe motion, probe wobble, or lift-off problems.

A known design for mounting test coils adjacent to the inner surface of the tube is depicted in U.S. Pat. No. 5,623,204 granted to Wilkerson on Apr. 22, 1997. In U.S. Pat. No. 5,623,204, a probe body incorporates two spring-loaded shoes which are biased to press outwardly against the inner surface of the tube through which the probe is being displaced. The shoes carry abrasion-resistant, tube-contacting wear faces having a low wear rate for contact with the tube inner wall. U.S. Pat. No. 5,623,204 also describes two matched test coils positioned adjacent to each other and individually carried within the respective shoes in such a manner that the ends of the test coils are facing the surface to be tested. The wear faces are positioned on either side of the coils carried within each individual shoe, thereby ensuring that the ends of the coils are positioned at a constant distance from the inner wall of the tube. Also according to this design, the probe body can be rotated through the use of a Bowden wire. Alternatively, the probe body may comprise a small, internally-mounted stepping motor that rotates a coil-carrying portion of the probe as this probe travels longitudinally along the interior of the tube.

Earlier U.S. Pat. No. 4,608,534 (Cecco et al.) issued on Aug. 26, 1986 gives an overview of eddy current probes used for internally or externally inspecting cylindrical components in view of localizing defects. For that purpose, a main coil arrangement induces and senses eddy currents in the cylindrical component. This patent also addresses an arrangement of coils for generating a defect-detecting signal distinct from a detected noise signal.

The instrumentation for eddy current testing in such applications includes not only a probe head with coils but also a signal generator and receiver equipment, cabling for connecting the probe to the signal generator and receiver equipment, a signal analyser equipment for analysing the data, and a display for providing an indication of defects in the material being tested. In the case of inspection of a tube, the cabling often includes a flexible positioning shaft or tube for positioning the probe along the length of, for example, steam generator tubes.

It is known as well to incorporate pancake-type coils into a probe body of the above-described Wilkerson design. In these applications, each shoe carries a single coil of a different size, each emitting a different frequency. The higher frequency coil inspects the inner wall of the tube while the lower frequency, having greater penetration capability, inspects the outer surface of the tube. However, the lower the frequency the less sensitive the measurement.

When inspecting for defects, the flow of the eddy currents is preferably as perpendicular as possible to the defects being sought to obtain maximum sensitivity. A flow of eddy current parallel to a defect produces a small distortion of the eddy current and hence little change in probe impedance. Pancake-type coils are too sensitive to variations in a tube under test, in particular lift-off, which reduces the signal/noise ratio for a defect either longitudinal or circumferential. For this reason, pancake-type coils are often deployed in conjunction with an orthogonal coil that is sensitive to most defects in the outer diameter of the tube. Orthogonal coils, however, produce a phase shift of 180 between longitudinal and circumferential defects of a same depth. This characteristic causes confusion during analysis of the defects when the two types of defects are simultaneously detected. Such a combination of coils is often utilized in an impedance measurement mode.

It has been demonstrated that pairs of pancake-type coils operating in a transmit-receive mode to inspect tubes for defects in both the axial and circumferential directions more reliably detect defects in steam generator tubes. This type of design is less sensitive to lift-off because it is surface riding, which also makes it more sensitive to defects because the coils are closer to the inner surface of the tube being inspected.

Currently, it is customary to initially evaluate the length of tubing under inspection using a probe carrying dual pancake-type coils in one shoe and one orthogonal coil in the second shoe on the opposite side of the probe. Then, having located areas of potential interest due to the likely presence of defects, it is necessary to introduce a second probe carrying a better discriminating coil sensing system to confirm or reject the presence of a defect at these particular areas. Although the probe carrying this better discriminating coil moves axially and rotates at the same speed as the initial probe, the time of inspection is more than doubled due to the necessity of changing the probe and repeating the inspection process.

There are several disadvantages related to this type of operation. First of all, the process of introducing two different types of probes into the tubing under test, as previously indicated, involves delay due to the time required to remove one probe from the tube and to replace it by the other probe. Since costs for a customer are generally proportional to the downtime arising from inspection, reducing the time necessary for the testing is a very important consideration. Secondly, exposure of the operator to a radioactive atmosphere associated with a nuclear reactor while the probes are being changed adds to the cumulative radiation level to which that operator has been exposed (also known as “dosage”). Understandably, the safety factor with regard to operator radiation dosage is of keen interest to the operators and to the overall well-being and efficient operation of a nuclear facility. Finally, difficulties arise when trying to compare the data acquired from two different measurement techniques because the data density (based on the speed of the probe in the tube and its rotation) is not identical. This is an added complication in the process of positively identifying a defect.

Starting about ten (10) years ago, a probe as described above containing an orthogonal coil in one shoe and two pancake-type coils of differing sizes in the second shoe was introduced into the NDT market for the inspection of small diameter tubes such as steam generator tubes in nuclear reactors. One such probe sold under the trademark +POINT EC by Zetec, Inc. soon became the standard for such inspections despite the drawbacks indicated above. This probe operates in the impedance mode.

Another eddy current probe is presently sold under the trademark RG3-4 by R/D Tech Inc. This probe is often used to confirm the initial detection of the presence of a defect by a +POINT EC™ probe. The RG3-4™ probe consists of three pancake-type coils mounted according to a L-shaped arrangement contained in a single, active shoe of the probe. This probe operated in the transmit-receive mode. This configuration of coils permits inspection along both the axial and circumferential axes of the tube under test with the driver coil being the coil at the intersection of the two arms of the “L”. In addition, this configuration enables reliable inspection through the entire wall thickness, including the outer diameter of the tube. The RG3-4™ probe is mechanically rotated to achieve full tube coverage while maintaining a high degree of resolution.

However, the RG3-4™ probe is costly and inconvenient since it requires two scans every time a tube is to be tested for defects. Although the RG3-4™ type probe can be successfully used in the above process, many users have used a +POINT EC™ type probes in the past and have extensive historical data using the latter probes, which data is very useful for the purpose of monitoring the “aging” of the tubes.

### SUMMARY OF THE INVENTION

To overcome the above discussed drawbacks of the prior art, the present invention proposes a dual sensitivity eddy current test probe for inspecting a tubular member made of electrically conducting material in order to detect and localize defects in the tubular member, comprising a probe body for movement about a surface of the tubular member, a first test coil assembly for detecting and localizing defects within the tubular member, a first support for the first test coil assembly, a second test coil assembly for acquiring historical data about defects in the tubular member, a second support for the second test coil assembly, and means for eliminating magnetic coupling interference between the first and second test coil assemblies. The first support is mounted on the probe body for holding the first test coil assembly at a first predetermined distance from the surface of the tubular member while the probe body moves about this surface of the tubular member. In the same manner, the second support is mounted on the probe body for holding the second test coil assembly at a second predetermined distance from the surface of the tubular member while the probe body moves about that surface of the tubular member.

The present invention also relates to a dual sensitivity eddy current test probe for inspecting a tubular member made of electrically conducting material in order to detect and localize defects in the tubular member, comprising:

a probe body for movement about a surface of the tubular member;

a first, test coil assembly for detecting and localizing defects within the tubular member;

a first support for the first test coil assembly, the first support being mounted on the probe body for holding the first test coil assembly at a first predetermined distance from the surface of the tubular member while the probe body moves about this surface of the tubular member;

a second test coil assembly for acquiring historical data about defects in the tubular member;

a second support for the second test coil assembly, the second support being mounted on the probe body for holding the second test coil assembly at a second predetermined distance from the surface of the tubular member while the probe body moves about this surface of the tubular member; and

magnetic coupling interference eliminating means interposed between the first and second test coil assemblies.

According to the present invention, there is provided a method for eliminating magnetic coupling interference in a dual sensitivity eddy current test probe for inspecting a tubular member made of electrically conducting material in order to detect and localize defects in the tubular member, wherein:

the dual sensitivity eddy current test probe comprises:

a probe body for movement about a surface of the tubular member;

a first test coil assembly for detecting and localizing defects within the tubular member;

a first support for the first test coil assembly, the first support being mounted on the probe body for holding the first test coil assembly at a first predetermined distance from the surface of the tubular member while the probe body moves about this surface of the tubular member;

a second test coil assembly for acquiring historical data about defects in the tubular member; and

a second support for the second test coil assembly, the second support being mounted on the probe body for holding the second test coil assembly at a second predetermined distance from the surface of the tubular member while the probe body moves about this surface of the tubular member;

the magnetic coupling interference eliminating method comprising:

supplying the first test coil assembly with a signal at a first frequency; and

supplying the second test coil assembly with a signal at a second frequency sufficiently remote from said first frequency to cause no magnetic coupling interference between the first and second test coil assemblies.

Also in accordance with the present invention, there is provided a method for eliminating magnetic coupling interference in a dual sensitivity eddy current test probe for inspecting a tubular member made of electrically conducting material in order to detect and localize defects in the tubular member, wherein:

the dual sensitivity eddy current test probe comprises:

a probe body for movement about a surface of the tubular member;

a first test coil assembly for detecting and localizing defects within the tubular member;

a first support for the first test coil assembly, the first support being mounted on the probe body for holding the first test coil assembly at a first predetermined distance from the surface of the tubular member while the probe body moves about this surface of the tubular member;

a second test coil assembly for acquiring historical data about defects in the tubular member; and

a second support for the second test coil assembly, the second support being mounted on the probe body for holding the second test coil assembly at a second predetermined distance from the surface of the tubular member while the probe body moves about this surface of the tubular member;

the magnetic coupling interference eliminating method comprises:

supplying a signal to the first test coil assembly during a first time slot; and

supplying a signal to the second test coil during a second time slot.

The foregoing and other objects, advantages and features of the present invention will become more apparent upon reading of the following non restrictive description of an illustrative embodiment thereof, given by way of example only with reference to the accompanying drawings.

### BRIEF DESCRIPTION OF THE DRAWINGS

In the appended drawings:

FIG. 1 is a perspective view of the non-restrictive illustrative embodiment of the dual sensitivity eddy current test probe according to the present invention;

FIG. 2 is a perspective, exploded view of the non-restrictive illustrative embodiment of the dual sensitivity eddy current test probe of FIG. 1;

FIG. 3 is a side, cross-sectional elevation view of the illustrative embodiment of dual sensitivity eddy current test probe of FIGS. 1 and 2;

FIG. 4 is a perspective view of an orthogonal coil forming part of the illustrative embodiment of the dual sensitivity eddy current test probe of FIGS. 1-3;

FIG. 5 is a top plan view of an outer trapezoidal side of a first shoe forming part of the illustrative embodiment of the dual sensitivity eddy current test probe of FIGS. 1-3, showing the position of the orthogonal coil of FIG. 4 on this first shoe;

FIG. 6 is a top plan view of an outer trapezoidal side of a second shoe forming part of the illustrative embodiment of the dual sensitivity eddy current test probe of FIGS. 1-3, showing the positions of three (3) pancake-type coils disposed in an L-shaped coplanar arrangement;

FIG. 7 is a schematic diagram showing a first example of circuit for the illustrative embodiment of the dual sensitivity eddy current test probe of FIGS. 1-3; and

FIG. 8 illustrates the configuration of the illustrative embodiment of the dual sensitivity eddy current test probe according to the present invention, provided with a third shoe bearing a large, low frequency pancake-type coil.

### DETAILED DESCRIPTION OF THE ILLUSTRATIVE EMBODIMENT

Although the non-restrictive illustrative embodiment of the dual sensitivity eddy current test probe according to the present invention will be described in relation to inspection of steam generator tubes of a nuclear plant, it should be kept in mind that the present invention can be applied to the inspection of other types of electrically conductive components.

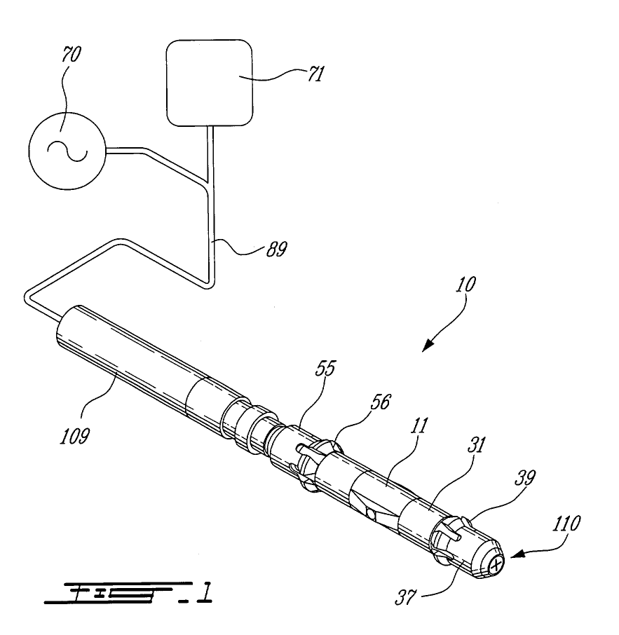

Referring to FIGS. 1-3 of the appended drawings, the non-restrictive illustrative embodiment of the dual sensitivity eddy current test probe is generally identified by the reference 10.

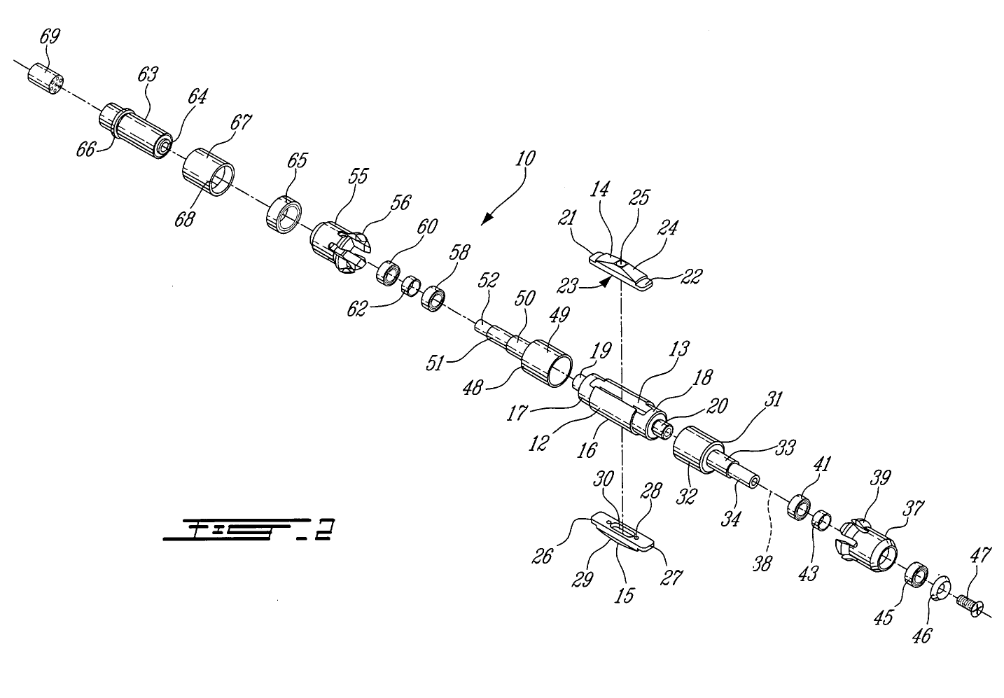

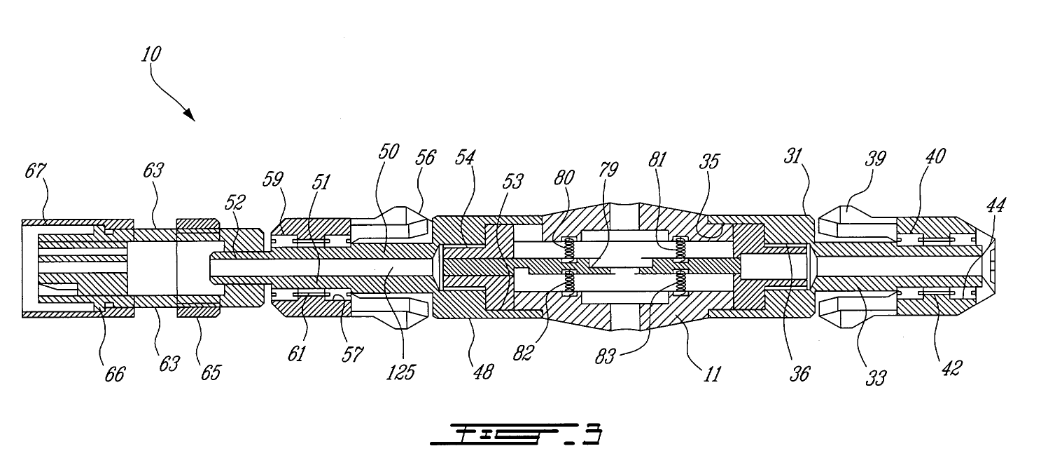

Probe 10 comprises a rotative coil carrier module 11 (FIG. 1). Referring to FIGS. 2 and 3, the coil carrier module 11 comprises a hollow cylindrical member 12 including a rectangular, diametrically extending opening 13 for receiving a pair of shoes 14 and 15 on diametrically opposite sides of the hollow cylindrical member 12. An axial, central flat wall 79 (FIG. 3) is left in the rectangular opening 13.

The hollow cylindrical member 12 comprises a central portion 16 of larger diameter, longitudinally opposite intermediate portions 17 and 18 of intermediate diameter, and longitudinally opposite end portions 19 and 20 of smaller diameter.

Shoe 14 presents the form of a bar having two end tabs 21 and 22. Shoe 14 has an inner flat side 23, an outer generally trapezoidal side 24, and a radial hole 25. In the same manner, shoe 15 presents the form of a bar having two end tabs 26 and 27. Shoe 15 also has an inner flat side 28, an outer generally trapezoidal side 29, and a radial hole 30.

Probe 10 further comprises a hollow cylindrical support member 31 having an outer surface with a larger diameter proximal portion 32, an intermediate portion 33 of intermediate diameter, and a distal free end portion 34 of smaller diameter. Internally of the larger diameter proximal portion 32 is formed a proximal larger diameter inner face 35 and a smaller diameter intermediate inner face 36. In operation, the smaller diameter intermediate inner face 36 is fitted on the end portion 20 of the hollow cylindrical member 12, while the proximal larger diameter inner face 35 is fitted on the intermediate portion 18 to lock the tabs 22 and 27 and therefore the shoes 14 and 15 in the rectangular opening 13.

Probe 10 is still further provided with a first cylindrical guide member 37 provided at the proximal end thereof with a plurality of trapezoidal guides such as 39 peripherally distributed around the longitudinal axis 38 of the probe 10. The inner face of the cylindrical guide member 37 is formed with a first larger diameter annular seat 40 for receiving a first ball bearing 41, a second larger diameter annular seat 44 for receiving a second ball bearing 45, and between the larger diameter seats 40 and 44 a third smaller diameter annular seat 42 for receiving an annular spacer 43 to be placed between the ball bearings 41 and 45. The ball bearings 41 and 45 received in the seats 40 and 44, respectively, are then placed on the distal free end portion 34 of the hollow cylindrical support member 31. This assembly is then held in place through a washer 46 and a screw 47 axially driven in a hole of the distal free end portion 34.

The trapezoidal guides such as 39 are then peripherally distributed around the intermediate portion 33 of the hollow cylindrical support member 31. Also, the hollow cylindrical support member 31 and, therefore, the coil carrier module 11 are free to rotate on the cylindrical guide member 37 through the ball bearings 41 and 45 about the longitudinal axis 38 of the probe 10.

Probe 10 comprises another hollow cylindrical support member 48 having an outer surface comprising, in series, a proximal portion 49 having a first larger diameter, an intermediate portion 50 having a second diameter smaller than the first diameter, another intermediate portion 51 having a third diameter smaller than the second diameter, and a distal free end portion 52 having a fourth diameter smaller than the third diameter. Internally of the larger diameter proximal portion 49 is formed a proximal larger diameter inner face 53 and a smaller diameter intermediate inner face 54. In operation, the smaller diameter intermediate inner face 54 is fitted on the end portion 19 of the hollow cylindrical member 12, while the proximal larger diameter inner face 53 is fitted on the intermediate portion 17 to lock the tabs 21 and 26 and therefore the shoes 14 and 15 in the rectangular opening 13.

The shoe 14 is biased outwardly by a pair of helical, longitudinally spaced apart springs 80 and 81. As illustrated in FIG. 3, helical spring 80 extends from a first hole in the inner flat side 23 of shoe 14 to a corresponding, radially aligned hole in the central flat wall 79 left in the rectangular opening 13. In the same manner, helical spring 81 extends from a second hole in the inner flat side 23 to a corresponding, radially aligned hole in the central flat wall 79. The proximal larger diameter inner face 53 of the hollow cylindrical support member 48 is fitted on the intermediate portion 17 of the hollow cylindrical member 12 and the proximal larger diameter inner face 35 of the hollow cylindrical support member 31 is fitted on the intermediate portion 18 of the hollow cylindrical member 12 to lock the tabs 21 and 22 and therefore the shoe 14 in the rectangular opening 13, against the biasing force produced by the two helical springs 80 and 81.

The shoe 15 is biased outwardly by a pair of helical, longitudinally spaced apart springs 82 and 83. As illustrated in FIG. 3, helical spring 82 extends from a first hole in the inner flat side 28 of shoe 15 to a corresponding, radially aligned hole in the central flat wall 79 left in the rectangular opening 13. In the same manner, helical spring 83 extends from a second hole in the inner flat side 28 to a corresponding, radially aligned hole in the central flat wall 79. The proximal larger diameter inner face 53 of the hollow cylindrical support member 48 is fitted on the intermediate portion 17 of the hollow cylindrical member 12 and the proximal larger diameter inner face 35 of the hollow cylindrical support member 31 is fitted on the intermediate portion 18 of the hollow cylindrical member 12 to lock the tabs 26 and 27 and therefore the shoe 15 in the rectangular opening 13, against the biasing force produced by the two helical springs 82 and 83.

Probe 10 is still further provided with a second cylindrical guide member 55 provided at the proximal end thereof with a plurality of trapezoidal guides such as 56 peripherally distributed around the longitudinal axis 38 of the probe 10. The inner face of the cylindrical guide member 55 is formed with a first larger diameter annular seat 57 for receiving a first ball bearing 58, a second larger diameter annular seat 59 for receiving a second ball bearing 60, and between the larger diameter seats 57 and 59 a third smaller diameter annular seat 61 for receiving an annular spacer 62 to be placed between the ball bearings 58 and 60. The ball bearings 58 and 60 received in the seats 57 and 59, respectively, are then placed on the intermediate portion 51 of the hollow cylindrical support member 48. This assembly is then held in place through a cylindrical tubular member 63 having a proximal end 64 fitted on the distal free end portion 52 of the hollow cylindrical support member 48. A sleeve 65 is mounted on the outer surface of the tubular member 63 to tighten the proximal end 64 of the cylindrical tubular member 63 on the distal free end portion 52 of the hollow cylindrical support member 48.

The trapezoidal guides such as 56 are then peripherally distributed around the intermediate portion 50 of the hollow cylindrical support member 48. Also, the hollow cylindrical support member 48 and, therefore, the coil carrier module 11 are free to rotate on the cylindrical guide member 55 through the ball bearings 58 and 60 about the longitudinal axis 38 of the probe 10.

The cylindrical tubular member 63 comprises an outer, annular rectangular protuberance 66. A cylinder 67 is longitudinally, slidably mounted on the outer surface of this cylindrical tubular member 63. To retain the cylinder 67 on the cylindrical tubular member 63 the cylinder 67 is formed with an inner shoulder 68 abutting on the rectangular protuberance 66.

A connector 69 is mounted within the distal end of the cylindrical tubular member 63 for connecting the probe 10 through a suitable cable 72 to a signal generating unit 70 and a receiver equipment 71 that may comprise a signal analyser equipment for analysing the collected data and a display for providing an indication of detects in the material being tested.

In the non-restrictive illustrative embodiment of the dual-sensitivity eddy current test probe 10 according to the present invention, one of the shoes, for example shoe 14, bears a coplanar L-shaped arrangement of three (3) pancake-type coils while the other shoe, for example shoe 15, bears an orthogonal coil.

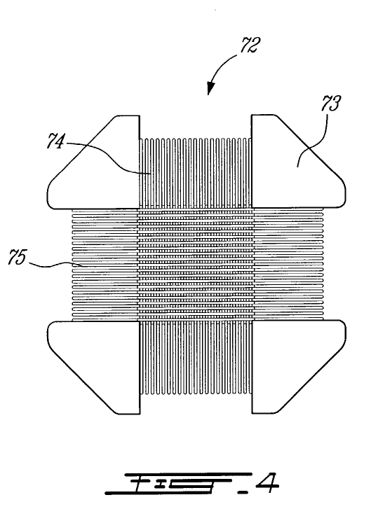

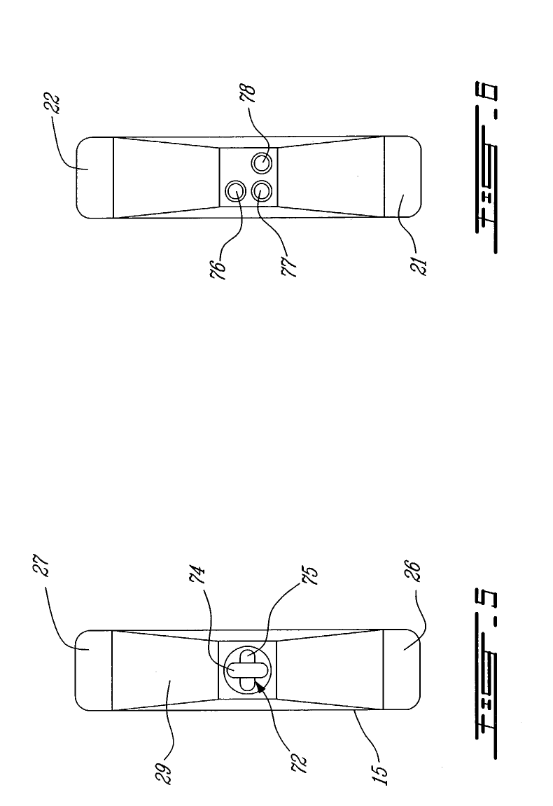

FIG. 4 illustrates an orthogonal coil 72 comprising two coils 74 and 75 wound on a common magnetic core 73 at right angle with respect to each other. FIG. 5 is a top plan view of the outer trapezoidal side 29 of the shoe 15 showing the orientation of the orthogonal coil 72 in the radial hole 30. The orthogonal coil 72 is embedded in, for example, epoxy filling the radial hole 30 to hold the orthogonal coil 72 in position in this radial hole 30. According to this design both coils 74 and 75 operate in a transmit-receive mode.

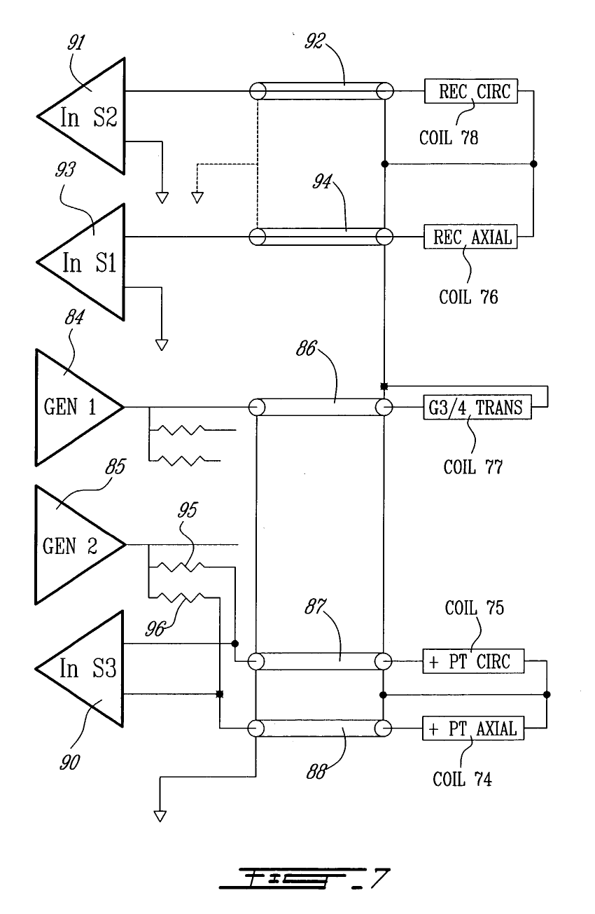

FIG. 6 is a top plan view of the outer trapezoidal side 24 of the shoe 14 showing the positions of the three (3) pancake-type coils of the above-mentioned L-shaped coplanar arrangement. More specifically, the shoe 14 bears three (3) pancake-type coils 76, 77 and 78 disposed in a common plane according to the L-shaped arrangement. Again the three (3) pancake-type coils 76, 77 and 78 are embedded in, for example, epoxy filling the radial hole 25 in order to hold these three (3) coils 76, 77 and 78 in position in this radial hole 25. According to a first alternative, coil 77 operates in the transmit-mode while coils 76 and 78 operate in the receive-mode. According to a second alternative, coils 76 and 78 operate in the transmit-mode while coil 77 operates in the receive-mode. Therefore, electrode pair 76 and 77 enables detection of circumferentially extending defects, while electrode pair 77 and 78 enables detection of longitudinally extending defects. The two alternatives result in a pairing of electrodes enabling detection of both circumferential and longitudinal defects.

Thus, the non-restrictive illustrative embodiment of the dual sensitivity eddy current test probe in accordance with the present invention comprises an orthogonal coil 72 in shoe 15 and three pancake-type coils 76, 77 and 78 in a L-shaped coplanar arrangement in the other shoe 14. The orthogonal coil 72 ensures the continuity of measurements that can be compared to historical data gathered by +POINT EC™ type probes in the past thereby reassuring the tube inspection community about the validity of the inspection results. Also, the L-shaped arrangement of pancake-type coils 76, 77 and 78 adds considerable sensitivity to the inspection due to the pairing of the coils in such a way as to allow both axial sensitivity and circumferential sensitivity without the negative effect of lift-off.

With the non-restrictive, illustrative embodiment of the present invention, a single scan enables simultaneously both:

To obtain, through the orthogonal coil, data useful for monitoring the “aging” of tubes that have been investigated in the past using +POINT ECT™ type probes and for which extensive historical data have been collected using the latter probes; and

Reliable inspection, through the L-shaped coplanar arrangement of three (3) pancake-type coils, of both the axial and circumferential directions of the tube through the entire wall thickness, while maintaining a high degree of resolution.

In the prior art, two scans were required to obtain similar results, with the corresponding disadvantages.

Proper operation of the non-restrictive illustrative embodiment of the dual sensitivity eddy current test probe 10 requires elimination of magnetic coupling interference between (a) the orthogonal coil 72 and (b) the three (3) pancake-type coils 76, 77 and 78.

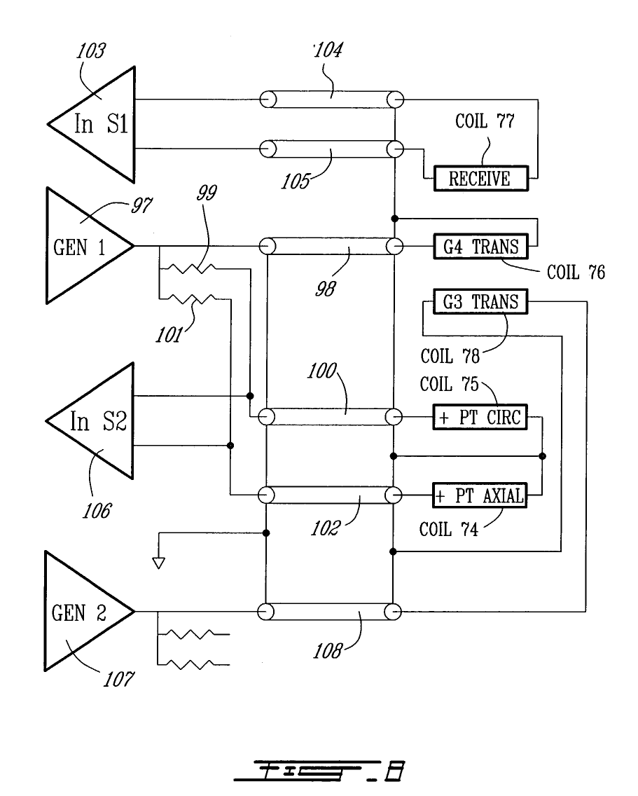

For that purpose, as illustrated in FIG. 7, two different signal sources 84 and 85 are used. Source 84 supplies the pancake-type coil 77 with a signal at a first frequency through a coaxial cable 86. Source 85 supplies the circumferential coil 75 with a second signal at a second frequency through a resistor 95 and a coaxial cable 87. In the same manner, source 85 supplies the axial coil 74 with the second signal at the second frequency through a resistor 96 and a coaxial cable 88. The first and second frequencies are sufficiently remote from each other to prevent any problem of magnetic coupling interference between (a) the orthogonal coil 72 and (b) the three (3) pancake-type coils 76, 77 and 78.

The first and second frequencies can also be modified accordance with the following pattern eliminating magnetic coupling interference:

| FIRST | SECOND |
|---|---|
| FREQUENCY | FREQUENCY |
| 100 MHz | 400 MHz |
| 200 MHz | 300 MHz |
| 300 MHz | 200 MHz |
| 400 MHz | 100 MHz |

The signal detected through the coils 78 of the L-shaped arrangement is supplied to signal analysing equipment 91 of the receiver equipment 71 of FIG. 1 through a coaxial cable 92. In the same manner, the signal detected through the coil 76 of the L-shaped arrangement is supplied to signal analysing equipment 93 of the receiver equipment 71 through a coaxial cable 94. Finally, the signal detected through the coils 74 and 75 of the orthogonal coil 72 is supplied to signal analysing equipment 90 of the receiver equipment 71 through the coaxial cables 87 and 88.

An alternative to eliminate the magnetic coupling interference is to use the same signal source or two different signal sources operating at the same frequency or at different frequencies to supply (a) the coil 77 and (b) the coils 74 and 75 during two different, respective time slots.

In the example of FIG. 7, the orthogonal coil 72 operates in an impedance mode whereas the three pancake-type coils 76, 77 and 78 operate in a transmit-receive mode.

In operation, an axial electrical motor 109 is mechanically connected to the connector 69 to rotate the assembly including the hollow cylindrical member 12 and the hollow cylindrical support members 31 and 48 about the longitudinal axis 38 and the cylindrical guide members 37 and 55. The electrical motor 109 includes a rotative connector (not shown).

The various coaxial cables (not shown) connected to the different coils extend through the inner cavity of the hollow cylindrical member 12 and, then, through an inner axial passage 125 in the hollow cylindrical support member 48 and the connector 69 to finally reach the rotative connector of the electrical motor 109. Other corresponding axial cables 89 then interconnect this rotative connector of the electrical motor 109 to the signal generating unit 70 and receiver equipment 71.

In operation, the non-restrictive illustrative embodiment of the dual sensitivity eddy current test probe 10 is inserted in a tube to be investigated. The nose 110 of the probe 10 is inserted first. Then, the probe 10 is supported within the tube under test by means of the trapezoidal guides 39 and 56 of the cylindrical guide members 37 and 55, these guides and guide members being dimensioned to snugly fit into the tube under investigation.

The electrical motor 109 is then energized to rotate the assembly including the hollow cylindrical member 12, the hollow cylindrical support members 31 and 48 about the longitudinal axis 38 and the cylindrical guide members 37 and 55. During this rotation, the springs 80 and 81 push on the shoe 14 to apply the trapezoidal side 24 of this shoe against the inner surface of the tube under test and thereby prevent lift-off. In the same manner, the springs 82 and 83 push on the shoe 15 to apply the trapezoidal side 29 of this shoe against the inner surface of the tube under test and thereby prevent lift-off.

The probe 10 is then displaced over the entire length of the tube to be tested in order to conduct proper measurement and investigation of this tube. For that purpose, the cabling 89 includes a flexible positioning shaft or tube for positioning the probe along the length of the tube under inspection.

The non-restrictive illustrative embodiment of the dual-sensitivity eddy current probe 10 has essentially the same outward appearance and dimensions of both the +POINT EC™ and RG3-4™ probes, both of which comprise two shoes. It has been unexpectedly found that it is possible to remove the two pancake-type coils in one of the shoes of the +POINT EC™ type probe and replace them with coils similar to those of the RG3-4™ type design. Therefore, the non-restrictive illustrative embodiment of the dual-sensitivity eddy current probe combines the main functionalities as described above of the existing +POINT EC™ type probe and RG3-4™ type probes into a single probe to obtain a new high performance eddy current probe. These two functionality include initially locating areas of potential presence of defects, and confirming or rejecting the presence of a defect at these particular areas during non-destructive testing of, in particular but not exclusively, steam generator tubes in a nuclear plant. In addition, the synergy between the two probes (shoes) of the combination yields a single probe having greater efficiency, increased safety for users in a nuclear plant environment, and sensitivity to both axial and circumferential defects at substantial lower cost to the user.

Therefore, the non-restrictive illustrative embodiment of the dual-sensitivity eddy current probe 10 presents, amongst others, the following advantages:

1. The probe is rotating and the shoes are surface riding. The surface riding aspect increases the sensitivity because the probe is touching the tube it is inspecting, therefore inhibiting the possibility of lift-off. Rotation is required to insure complete inspection coverage of the entire volume of the tube walls under inspection.

2. The non-restrictive illustrative embodiment of the dual-sensitivity eddy current probe 10 decreases the time of inspection.

3. The non-restrictive illustrative embodiment of the dual-sensitivity eddy current probe 10 increases the sensitivity of defect detection.

4. The non-restrictive illustrative embodiment of the dual-sensitivity eddy current probe 10 reduces the radiation dosage to which workers in nuclear reactors are exposed during the inspection of steam generator tubes in nuclear reactors.

5. The non-restrictive illustrative embodiment of the dual-sensitivity eddy current probe 10 allows reliable comparison of the data provided by the two types of measurements because both will be based on the same data density as determined by common axial and rotational speeds of the probe.

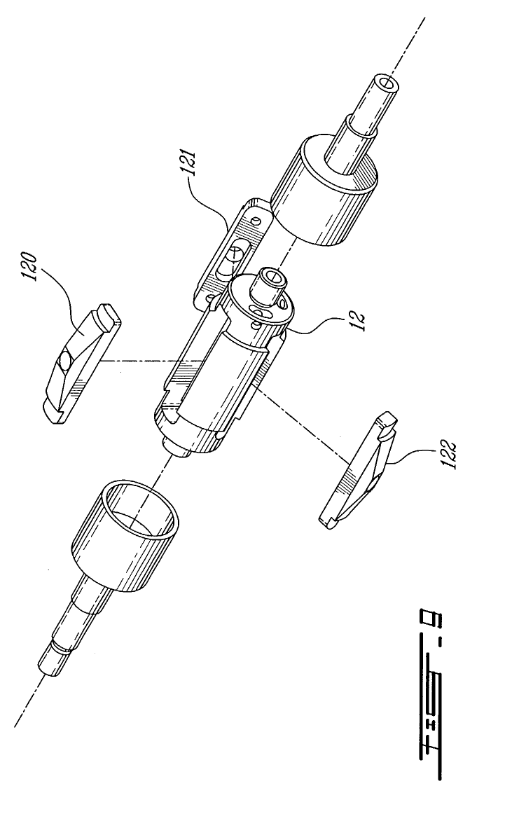

In the above-described non-restrictive illustrative embodiment of the dual-sensitivity eddy current probe 10, two (2) shoes are provided. However, it is within the scope of the present invention to provide a dual-sensitivity eddy current probe 10 with more than two (2) shoes. For example, a third shoe placed symmetrically on the probe with respect to the other two (2) shoes, could carry a large pancake-type coil that operates at low frequency to give a redundant inspection at the outer diameter of the tube where most defects occur due to corrosion. An example of the disposition of such three (3) shoes 120, 121 and 122, 120° apart from each other about the axis 38 of the hollow cylindrical member 12 is illustrated in FIG. 8. In this illustrative embodiment, shoes 120 and 121 correspond to shoes 14 and 15 of FIG. 2 while shoe 122 bears the above-mentioned large, low frequency pancake-type coil.

Although the illustrative embodiment of the present invention has been described in the foregoing description with reference to an illustrative embodiment thereof, this embodiment can be modified at will, within the scope of the appended claims without departing from the scope and nature of the subject invention.

What is claimed is:

1. A dual sensitivity eddy current test probe for inspecting a tubular member to detect and localize defects in the tubular member, the tubular member being composed of an electrically conducting material, comprising:
a probe body moving about a surface of the tubular member;
a first test coil assembly detecting and localizing defects within the tubular member;
a first support arrangement supporting the first test coil assembly, the first support arrangement being mounted on the probe body and holding the first test coil assembly at a first predetermined distance from the surface of the tubular member while the probe body moves about the surface of the tubular member;
a second test coil assembly acquiring historical data regarding defects in the tubular member;
a second support arrangement supporting the second test coil assembly, the second support arrangement being mounted on the probe body and holding the second test coil assembly at a second predetermined distance from the surface of the tubular member while the probe body moves about the surface of the tubular member; and
an arrangement eliminating a magnetic coupling interference between the first and second test coil assemblies.

2. A dual sensitivity eddy current test probe for inspecting a tubular member to detect and localize defects in the tubular member, the tubular member being composed of an electrically conducting material, comprising:
a probe body moving about a surface of the tubular member;
a first test coil assembly detecting and localizing defects within the tubular member;
a first support arrangement supporting the first test coil assembly, the first support arrangement being mounted on the probe body and holding the first test coil assembly at a first predetermined distance from the surface of the tubular member while the probe body moves about the surface of the tubular member;
a second test coil assembly acquiring historical data regarding defects in the tubular member;
a second support arrangement supporting the second test coil assembly, the second support arrangement being mounted on the probe body and holding the second test coil assembly at a second predetermined distance from the surface of the tubular member while the probe body moves about the surface of the tubular member; and
a magnetic coupling interference eliminating arrangement being interposed between the first and second test coil assemblies.

3. A dual sensitivity eddy current test probe as defined in claim 2, wherein the first test coil assembly includes three substantially coplanar pancake-type coils disposed in an L-shaped manner.

4. A dual sensitivity eddy current test probe as defined in claim 2, wherein the second test coil assembly includes an orthogonal coil.

5. A dual sensitivity eddy current test probe as defined in claim 2, wherein the first test coil assembly includes three substantially coplanar pancake-type coils disposed in an L-shaped manner, the second test coil assembly including an orthogonal coil, and wherein the dual sensitivity eddy current test probe further comprises:
a third low frequency test coil assembly including a pancake-type coil; and
a third support arrangement supporting the third test coil assembly, the third support arrangement being mounted on the probe body and holding the third test coil assembly at a third predetermined distance from the surface of the tubular member while the probe body moves about the surface of the tubular member.

6. A dual sensitivity eddy current test probe as defined in claim 2, further comprising:
a third low frequency test coil assembly; and
a third support arrangement supporting the third test coil assembly, the third support arrangement being mounted on the probe body and holding the third test coil assembly at a third predetermined distance from the surface of the tubular member while the probe body moves about the surface of the tubular member.

7. A dual sensitivity eddy current test probe as defined in claim 3, further comprising:
a second arrangement operating the three substantially coplanar pancake-type coils in a transmit-receive mode.

8. A dual sensitivity eddy current test probe as defined in claim 4, further comprising:
a third arrangement operating the orthogonal coil in an impedance mode.

9. A dual sensitivity eddy current test probe as defined in claim 2, wherein the magnetic coupling interference eliminating arrangement includes:
a first signal source connected to the first test coil assembly and supplying the first test coil assembly with a first signal at a first frequency, and
a second signal source connected to the second test coil assembly and supplying the second test coil assembly with a second signal at a second frequency sufficiently remote from the first frequency to prevent magnetic coupling interference between the first and second test coil assemblies.

10. A dual sensitivity eddy current test probe as defined in claim 9, wherein each of the first and second signal sources includes a frequency varying arrangement varying the first and second frequencies of the first and second signals supplied to the first and second test coil assemblies.

11. A dual sensitivity eddy current test probe as defined in claim 2, wherein the magnetic coupling interference eliminating arrangement includes a signal source system which includes a first arrangement supplying a first signal to the first test coil assembly during a first time slot and a second arrangement supplying a second signal to the second test coil during a second time slot.

12. A dual sensitivity eddy current test probe as defined in claim 2, wherein the magnetic coupling interference eliminating arrangement includes:
a first signal source connected to the first and second test coil assemblies and supplying a first signal to the first and second test coil assemblies during a first time slot; and
a second signal source connected to the first test coil assembly and supplying a second signal to the first test coil assembly only during a second time slot to prevent magnetic coupling interference during the second time slot.

13. A method for eliminating a magnetic coupling interference in a dual sensitivity eddy current test probe and inspecting a tubular member to detect and localize defects in the tubular member, the tubular member being composed of an electrically conducting material, the method comprising the steps of:
supplying a first test coil assembly of the test probe with a first signal at a first frequency; and
supplying a second test coil assembly of the test probe with a second signal at a second frequency sufficiently remote from the first frequency to prevent magnetic coupling interference between the first and second test coil assemblies,
wherein the test probe further includes a probe body moving about a surface of the tubular member, a first support arrangement supporting the first test coil assembly and a second support arrangement supporting the second test coil assembly, the first test coil assembly being utilized for detecting and localizing defects within the tubular member, the second test coil assembly being utilized for acquiring historical data regarding defects in the tubular member, the first support arrangement being mounted on the probe body and holding the first test coil assembly at a first predetermined distance from the surface of the tubular member while the probe body moves about the surface of the tubular member, the second support arrangement being mounted on the probe body and holding the second test coil assembly at a second predetermined distance from the surface of the tubular member while the probe body moves about the surface of the tubular member.

14. A method for eliminating magnetic coupling interference as defined in claim 13, further comprising:
varying the first and second frequencies of the signals supplied to the first and second test coil assemblies.

15. A method for eliminating a magnetic coupling interference in a dual sensitivity eddy current test probe and inspecting a tubular member to detect and localize defects in the tubular member, the tubular member being composed of an electrically conducting material, comprising the steps of:
supplying a first signal to a first test coil assembly of the test probe during a first time slot; and
supplying a second signal to a second test coil of the test probe during a second time slot,
wherein the test probe further includes a probe body moving about a surface of the tubular member, a first support arrangement and a second support arrangement, the first test coil assembly detecting and localizing defects within the tubular member, the first support being mounted on the probe body and supporting the first test coil assembly at a first predetermined distance from the surface of the tubular member while the probe body moves regarding the surface of the tubular member, the second test coil assembly being utilized for acquiring historical data about defects in the tubular member, the second support being mounted on the probe body and supporting the second test coil assembly at a second predetermined distance from the surface of the tubular member while the probe body moves about the surface of the tubular member.
